(19) United States
(12) Patent Application Publication
(10) Pub. No.: US 2025/0266383 A1
(43) Pub. Date: Aug. 21, 2025

(54) CONDUCTIVE BUMP STRUCTURE AND MANUFACTURING METHOD THEREOF

(71) Applicant: SILICONWARE PRECISION INDUSTRIES CO., LTD., Taichung City (TW)

(72) Inventors: Po-Yi WU, Taichung City (TW); Hsiang-Yang LIN, Taichung City (TW)

(73) Assignee: SILICONWARE PRECISION INDUSTRIES CO., LTD., Taichung City (TW)

(21) Appl. No.: 19/018,443

(22) Filed: Jan. 13, 2025

(30) Foreign Application Priority Data
Feb. 20, 2024 (TW) 113106010

(51) Int. Cl. H01L 23/00; H01L 21/48; H01L 23/13; H01L 23/15; H01L 23/498

(52) U.S. Cl. CPC H01L 24/13; H01L 21/4857; H01L 23/13; H01L 23/49822; H01L 24/04; H01L 23/15; H01L 23/49894; H01L 24/05; H01L 2224/0401; H01L 2224/05624; H01L 2224/13006; H01L 2224/13021; H01L 2224/13024; H01L 2924/35121

(57) ABSTRACT

A conductive bump structure and a manufacturing method thereof are provided. A first insulating layer is formed on a semiconductor substrate having bonding pads and a protective layer, and the first insulating layer has first openings and second openings, so that the bonding pads are exposed from the first openings, and portions of the protective layer are exposed from the second openings. A metal layer electrically connected to the bonding pads is formed on the first insulating layer. A second insulating layer is formed on the first insulating layer and the metal layer. The second insulating layer has third openings corresponding to positions of the second openings, so each of the second openings and each of the third openings together form a groove structure. A conductive metal layer electrically connected to the metal layer is formed in the groove structure. Metal bumps are formed on the conductive metal layer.

### BACKGROUND

### 1. Technical Field

The present disclosure relates to a conductive bump, and more particularly, to a conductive bump structure formed on a semiconductor substrate and a manufacturing method thereof.

### 2. Description of Related Art

With the advancement of semiconductor process technology and the continuous improvement of chip circuit functions, the demand for various portable products in fields such as communications, networks and computers has grown significantly. Therefore, semiconductor packaging technologies such as ball grid array (BGA), flip chip and chip size package (CSP) that can reduce the integrated circuit (IC) area and has high density and multi-pin characteristics have become mainstream.

Compared with wire bonding technology, the characteristic of flip chip package is that the electrical connection between the semiconductor chip and the package substrate is via solder bumps instead of ordinary gold wires. Using solder bumps as electrical connection components has the advantages of reducing electrical conduction paths, improving performance, providing heat dissipation paths and reducing package size, and has therefore become a trend for packaging.

Referring to FIG. 1A to FIG. 1D, a method for manufacturing a conventional solder bump comprises providing a wafer 10, wherein the wafer 10 is covered with a protective layer 11, and a bonding pad 100 is exposed from the protective layer 11. Then, a first insulating layer 12 is formed on the wafer 10, and a first opening 120 is formed on the first insulating layer 12 to expose the bonding pad 100. Next, a redistribution layer (RDL) 13 is formed on the first insulating layer 12, a second insulating layer 14 is formed on the redistribution layer 13, and a second opening 140 is formed on the second insulating layer 14 to expose a portion of the redistribution layer 13. An under bump metallization (UBM) layer 15 is formed on the exposed portion of the redistribution layer 13, and a solder material is formed on the under bump metallization layer 15 to form a solder bump 16.

However, considering the increase in the number of input/output (I/O) in a semiconductor chip and the density of the redistribution layer, the contact area between homogeneous insulating layers will decrease. Accordingly, the contact area between the insulating layer and the heterogeneous copper circuit (the redistribution layer) increases, thereby causing delamination (De-lam) problem between the copper circuit and the insulating layer.

Therefore, how to overcome the above-mentioned drawbacks of the prior art has become an urgent issue to be solved.

### SUMMARY

In view of the various deficiencies of the prior art, the present disclosure provides a conductive bump structure formed on a semiconductor substrate having bonding pads and a protective layer, the conductive bump structure comprises: a first insulating layer formed on the protective layer and having first openings and second openings, wherein the first openings correspond to positions of the bonding pads, so that the bonding pads are exposed from the first openings, and the second openings correspond to a position of the protective layer, so that portions of the protective layer are exposed from the second openings; a metal layer formed on the first insulating layer and electrically connected to the bonding pads; a second insulating layer formed on the first insulating layer and the metal layer, wherein the second insulating layer is formed with third openings corresponding to positions of the second openings, so that each of the second openings and each of the third openings together form a groove structure; a conductive metal layer formed in the groove structure and electrically connected to the metal layer; and metal bumps formed on the conductive metal layer.

The present disclosure also provides a method of manufacturing a conductive bump structure, the method comprises: forming a first insulating layer on a semiconductor substrate having bonding pads and a protective layer, and forming first openings and second openings on the first insulating layer, wherein the first openings correspond to positions of the bonding pads, so that the bonding pads are exposed from the first openings, and the second openings correspond to a position of the protective layer, so that portions of the protective layer are exposed from the second openings; forming a metal layer electrically connected to the bonding pads on the first insulating layer; forming a second insulating layer on the first insulating layer and the metal layer, wherein the second insulating layer is formed with third openings corresponding to positions of the second openings, so that each of the second openings and each of the third openings together form a groove structure; forming a conductive metal layer electrically connected to the metal layer in the groove structure; and forming metal bumps on the conductive metal layer.

In the aforementioned conductive bump structure and method, the metal layer is a redistribution layer.

In the aforementioned conductive bump structure and method, the metal layer is formed on the first insulating layer, the bonding pads exposed from the first openings, and the protective layer exposed from the second openings.

In the aforementioned conductive bump structure and method, the metal layer is formed on the first insulating layer and the bonding pads exposed from the first openings, and the metal layer does not extend to the protective layer exposed from the second openings.

In the aforementioned conductive bump structure and method, the conductive metal layer is an under bump metallization layer.

In the aforementioned conductive bump structure and method, a size of each of the third openings is larger than a size of each of the second openings, so that each of the second openings and each of the third openings together form a stepped groove structure.

As can be seen from the above, in the conductive bump structure and the manufacturing method thereof of the present disclosure, the second opening of the first insulating layer under the metal bump is opened in advance together with the first opening of the first insulating layer on the bonding pad, and the third opening of the second insulating layer corresponds to the position of the second opening to form a stepped groove structure. Accordingly, the stress at the interface of the first insulating layer, the second insulating layer, the metal layer (RDL) and the conductive metal layer (UBM) is dispersed to prevent stress from being concentrated on the interface of different materials and causing delamination problems.

### BRIEF DESCRIPTION OF THE DRAWINGS

FIG. 1A to FIG. 1D are schematic cross-sectional views illustrating a manufacturing process of a conventional solder bump.

FIG. 2A to FIG. 2E are schematic cross-sectional views illustrating a manufacturing method of a conductive bump structure according to a first embodiment of the present disclosure.

FIG. 3A to FIG. 3E are schematic cross-sectional views illustrating a manufacturing method of a conductive bump structure according to a second embodiment of the present disclosure.

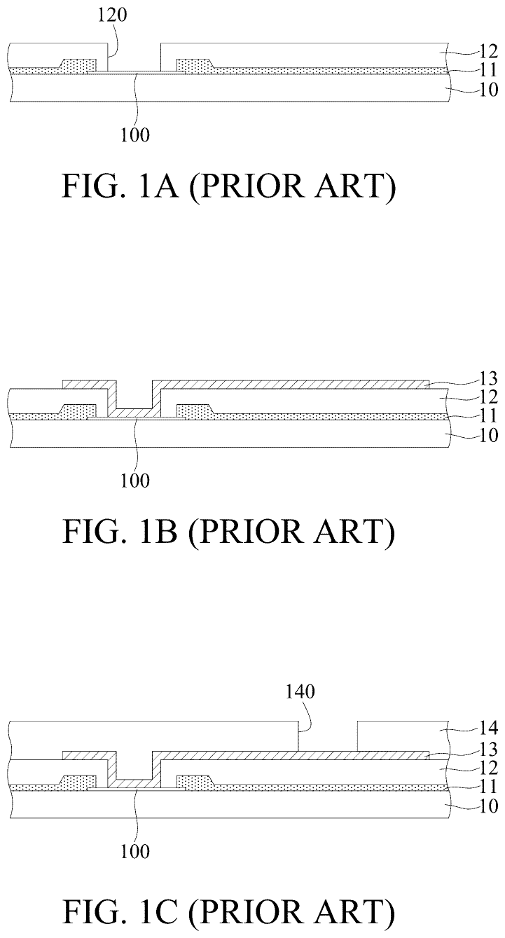

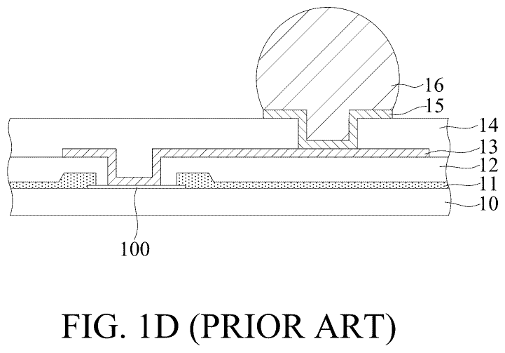

### DETAILED DESCRIPTION

The following describes the embodiments of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “a,” “one,” and the like are merely used for clear explanation rather than limiting the practicable scope of the present disclosure, and thus, alterations or adjustments of the relative relationships thereof without essentially altering the technical contents should still be considered in the practicable scope of the present disclosure.

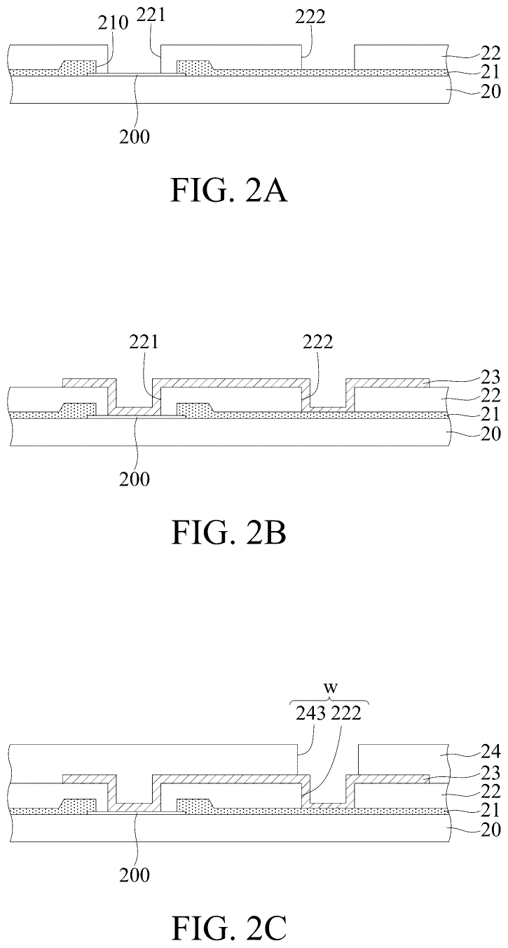

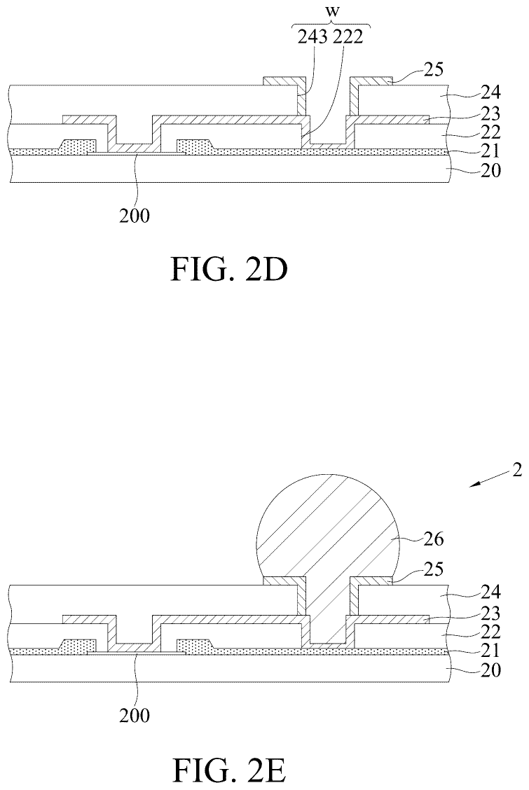

Please refer to FIG. 2A to FIG. 2E, which are schematic cross-sectional views illustrating a method for manufacturing a conductive bump structure according to a first embodiment of the present disclosure. The conductive bump structure is formed on a semiconductor substrate such as a wafer or chip.

As shown in FIG. 2A, a semiconductor substrate 20 having a plurality of bonding pads 200 is provided, wherein only a single bonding pad is shown in the drawing because the processes performed on each of the bonding pads are similar.

In one embodiment, the semiconductor substrate 20 is a wafer, but in other embodiments, the semiconductor substrate 20 can also be a silicon substrate or a glass substrate. The semiconductor substrate 20 is covered with a protective layer 21, and the protective layer 21 has a plurality of holes 210 so that the plurality of bonding pads 200 are correspondingly exposed from the plurality of holes 210. Furthermore, the material for forming the bonding pad 200 can be aluminum, and the material for forming the protective layer 21 can be silicon nitride (SiN) or silicon oxide compound (SiOx) to serve as a passivation layer.

Next, a first insulating layer 22 is formed on the protective layer 21, and a plurality of first openings 221 and a plurality of second openings 222 are formed on the first insulating layer 22. The first openings 221 correspond to positions of the bonding pads 200, so that the bonding pads 200 are exposed from the first insulating layer 22. The second openings 222 do not correspond to the positions of the bonding pads 200, so that portions of the protective layer 21 are exposed from the first insulating layer 22. In one embodiment, the first insulating layer 22 may be made of polyimide (PI), benzocyclobutene (BCB), or polybenzoxazole (PBO).

As shown in FIG. 2B, a metal layer 23 is formed on the first insulating layer 22, the bonding pads 200 exposed from the first openings 221, and the protective layer 21 exposed from the second openings 222. In one embodiment, the metal layer 23 is a copper layer and serves as a redistribution layer, and the metal layer 23 is electrically connected to the bonding pads 200.

As shown in FIG. 2C, a second insulating layer 24 is formed on the first insulating layer 22 and the metal layer 23, and a plurality of third openings 243 are formed on the second insulating layer 24, wherein the third openings 243 correspond to positions of the second openings 222, so that the metal layer 23 formed in the second openings 222 is exposed from the third openings 243. In one embodiment, the size of each of the third openings 243 is larger than the size of each of the second openings 222, so that each of the second openings 222 and each of the third openings 243 together form a stepped groove structure w (e.g., a step-shaped groove structure).

As shown in FIG. 2D, a conductive metal layer 25 is formed in the stepped groove structure w to serve as an under bump metallization (UBM) layer, and the conductive metal layer 25 is electrically connected to the metal layer 23 (the redistribution layer). In one embodiment, the material for forming the conductive metal layer 25 can be titanium/copper (Ti/Cu) or titanium/tungsten/copper (Ti/W/Cu), and the conductive metal layer 25 is stacked on the metal layer 23 exposed from the second openings 222.

As shown in FIG. 2E, a metal bump 26 is formed on the conductive metal layer 25 to obtain a conductive bump structure 2 of the present disclosure. In one embodiment, the metal bump 26 is, for example, a solder bump.

As can be seen from the aforementioned manufacturing method, in the present disclosure, the second opening of the first insulating layer under the metal bump is opened in advance together with the first opening of the first insulating layer on the bonding pad, and the third opening of the second insulating layer corresponds to the position of the second opening to form a stepped groove structure. Accordingly, the stress at the interface of the first insulating layer, the second insulating layer, the metal layer (RDL) and the conductive metal layer (UBM) is dispersed in a stepwise manner to prevent stress from being concentrated on the interface of different materials and causing delamination problems.

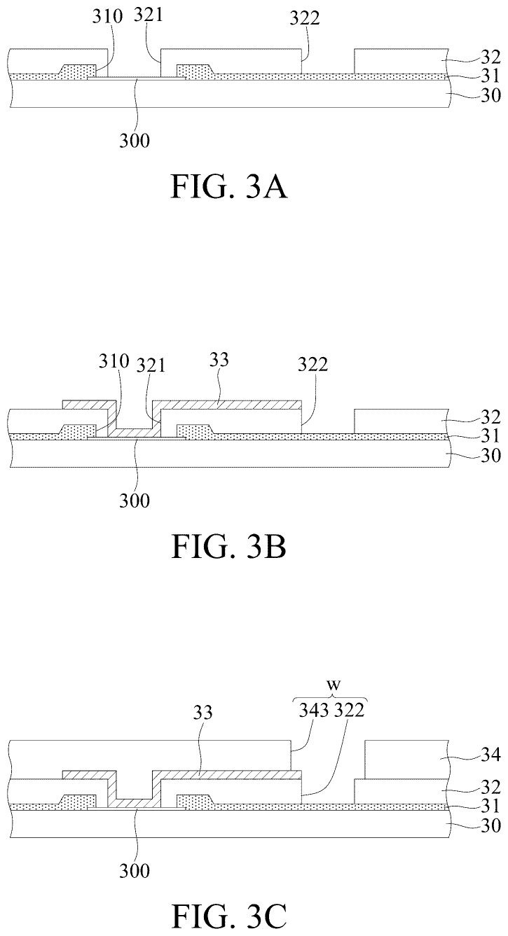

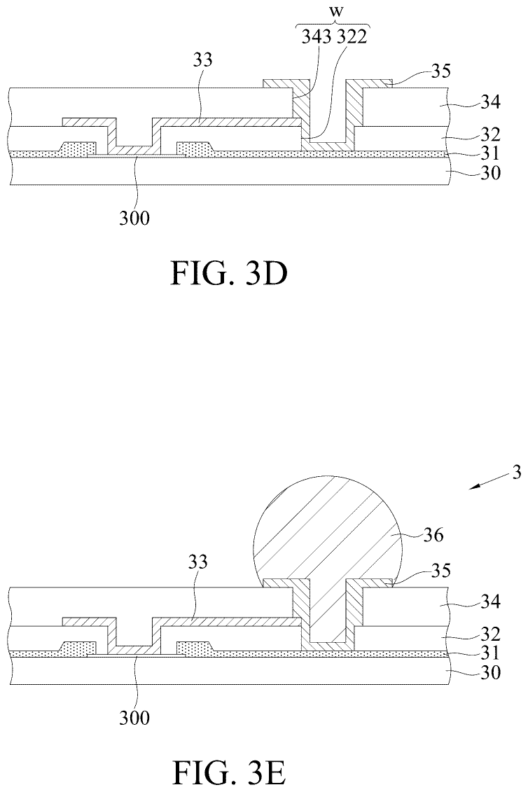

Please refer to FIG. 3A to FIG. 3E, which are schematic cross-sectional views illustrating a method for manufacturing a conductive bump structure according to a second embodiment of the present disclosure. The main difference between the second embodiment and the first embodiment lies in the change in the layout range of the metal layer (RDL). Other related processes are substantially the same, so the similarities will not be restated below.

As shown in FIG. 3A, a semiconductor substrate 30 having a plurality of bonding pads 300 is provided. The semiconductor substrate 30 is covered with a protective layer 31, and the protective layer 31 has a plurality of holes 310 so that the plurality of bonding pads 300 are correspondingly exposed from the plurality of holes 310. Next, a first insulating layer 32 is formed on the protective layer 31, and a plurality of first openings 321 and a plurality of second openings 322 are formed on the first insulating layer 32. The first openings 321 correspond to positions of the bonding pads 300, so that the bonding pads 300 are exposed from the first insulating layer 32. The second openings 322 do not correspond to the positions of the bonding pads 300, so that portions of the protective layer 31 are exposed from the first insulating layer 32.

As shown in FIG. 3B, a metal layer 33 (RDL) is formed on the first insulating layer 32 and the bonding pads 300 exposed from the first openings 321, and the metal layer 33 is electrically connected to the bonding pads 300. Different from the aforementioned first embodiment, the metal layer 33 in the second embodiment does not extend to the protective layer 31 exposed from the second openings 322.

As shown in FIG. 3C, a second insulating layer 34 is formed on the first insulating layer 32 and the metal layer 33, and a plurality of third openings 343 are formed on the second insulating layer 34. The third openings 343 correspond to positions of the second openings 322 to expose the protective layer 31 exposed from the second openings 322 and portions of the metal layer 33 formed on the first insulating layer 32. The size of each of the third openings 343 is larger than the size of each of the second openings 322, so that each of the second openings 322 and each of the third openings 343 together form a stepped groove structure w (e.g., a step-shaped groove structure). Accordingly, portions of the protective layer 31 are exposed, and portions of the metal layer 33 formed on the first insulating layer 32 are exposed.

As shown in FIG. 3D, a conductive metal layer 35 is formed in the stepped groove structure w to serve as an under bump metallization (UBM) layer, and the conductive metal layer 35 is electrically connected to the metal layer 33 formed on the first insulating layer 32.

As shown in FIG. 3E, a metal bump 36 is formed on the conductive metal layer 35 to obtain a conductive bump structure 3 of the present disclosure.

As can be seen from the foregoing manufacturing method, in the present disclosure, the second opening of the first insulating layer under the metal bump is opened in advance together with the first opening of the first insulating layer on the bonding pad, and the third opening of the second insulating layer corresponds to the position of the second opening to form a stepped groove structure. Accordingly, the stress at the interface of the first insulating layer, the second insulating layer, the metal layer (RDL) and the conductive metal layer (UBM) is dispersed in a stepwise manner while the metal layer does not extend to the second opening. Therefore, the density of metal layer is reduced, and the contact area/surface between homogeneous insulating layers is increased to reduce stress and avoid delamination problems caused by stress concentration on the interface of different materials.

The present disclosure further provides a conductive bump structure 2, 3 formed on a semiconductor substrate 20, 30. The semiconductor substrate 20, 30 has bonding pads 200, 300 and a protective layer 21, 31. The protective layer 21, 31 is formed with holes 210, 310 so that the bonding pads 200, 300 are exposed from the holes 210, 310. The conductive bump structure 2, 3 includes: a first insulating layer 22, 32, which is formed on the protective layer 21, 31 and has first openings 221, 321 and second openings 222, 322, wherein the first openings 221, 321 correspond to positions of the bonding pads 200, 300, so that the bonding pads 200, 300 are exposed from the first openings 221, 321, and the second openings 222, 322 correspond to position(s) of the protective layer 21, 31, so that portions of the protective layer 21, 31 are exposed from the second openings 222, 322; a metal layer 23, 33 formed on the first insulating layer 22, 32 and electrically connected to the bonding pads 200, 300; a second insulating layer 24, 34 formed on the first insulating layer 22, 32 and the metal layer 23, 33, wherein the second insulating layer 24, 34 is formed with third openings 243, 343 corresponding to positions of the second openings 222, 322, so that each of the second openings 222, 322 and each of the third openings 243, 343 together form a groove structure w; a conductive metal layer 25, 35 formed in the groove structure w and electrically connected to the metal layer 23, 33; and metal bumps 26, 36 formed on the conductive metal layer 25, 35.

The metal layer 23, 33 is a redistribution layer. In one embodiment, the metal layer 23 is formed on the first insulating layer 22, the bonding pads 200 exposed from the first openings 221, and the protective layer 21 exposed from the second openings 222. In another embodiment, the metal layer 33 is formed on the first insulating layer 32 and the bonding pads 300 exposed from the first openings 321, and the metal layer 33 does not extend to the protective layer 31 exposed from the second openings 322.

The conductive metal layer 25, 35 is an under bump metallization layer.

The size of each of the third openings 243, 343 is larger than the size of each of the second openings 222, 322, so that each of the second openings 222, 322 and each of the third openings 243, 343 together form a stepped groove structure w.

To sum up, in the conductive bump structure and the manufacturing method thereof of the present disclosure, the second opening of the first insulating layer under the metal bump is opened in advance together with the first opening of the first insulating layer on the bonding pad, and the third opening of the second insulating layer corresponds to the position of the second opening to form a stepped groove structure. Accordingly, the stress at the interface of the first insulating layer, the second insulating layer, the metal layer (RDL) and the conductive metal layer (UBM) is dispersed to prevent stress from being concentrated on the interface of different materials and causing delamination problems.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A conductive bump structure formed on a semiconductor substrate having bonding pads and a protective layer, the conductive bump structure comprising:
a first insulating layer formed on the protective layer and having first openings and second openings, wherein the first openings correspond to positions of the bonding pads, so that the bonding pads are exposed from the first openings, and the second openings correspond to a position of the protective layer, so that portions of the protective layer are exposed from the second openings;
a metal layer formed on the first insulating layer and electrically connected to the bonding pads;
a second insulating layer formed on the first insulating layer and the metal layer, wherein the second insulating layer is formed with third openings corresponding to positions of the second openings, so that each of the second openings and each of the third openings together form a groove structure;
a conductive metal layer formed in the groove structure and electrically connected to the metal layer; and
metal bumps formed on the conductive metal layer.

2. The conductive bump structure of claim 1, wherein the metal layer is a redistribution layer.

3. The conductive bump structure of claim 1, wherein the metal layer is formed on the first insulating layer, the bonding pads exposed from the first openings, and the protective layer exposed from the second openings.

4. The conductive bump structure of claim 1, wherein the metal layer is formed on the first insulating layer and the bonding pads exposed from the first openings, and the metal layer does not extend to the protective layer exposed from the second openings.

5. The conductive bump structure of claim 1, wherein the conductive metal layer is an under bump metallization layer.

6. The conductive bump structure of claim 1, wherein a size of each of the third openings is larger than a size of each of the second openings, so that each of the second openings and each of the third openings together form a stepped groove structure.

7. A method of manufacturing a conductive bump structure, comprising:
forming a first insulating layer on a semiconductor substrate having bonding pads and a protective layer, and forming first openings and second openings on the first insulating layer, wherein the first openings correspond to positions of the bonding pads, so that the bonding pads are exposed from the first openings, and the second openings correspond to a position of the protective layer, so that portions of the protective layer are exposed from the second openings;
forming a metal layer electrically connected to the bonding pads on the first insulating layer;
forming a second insulating layer on the first insulating layer and the metal layer, wherein the second insulating layer is formed with third openings corresponding to positions of the second openings, so that each of the second openings and each of the third openings together form a groove structure;
forming a conductive metal layer electrically connected to the metal layer in the groove structure; and
forming metal bumps on the conductive metal layer.

8. The method of claim 7, wherein the metal layer is a redistribution layer.

9. The method of claim 7, wherein the metal layer is formed on the first insulating layer, the bonding pads exposed from the first openings, and the protective layer exposed from the second openings.

10. The method of claim 7, wherein the metal layer is formed on the first insulating layer and the bonding pads exposed from the first openings, and the metal layer does not extend to the protective layer exposed from the second openings.

11. The method of claim 7, wherein the conductive metal layer is an under bump metallization layer.

12. The method of claim 7, wherein a size of each of the third openings is larger than a size of each of the second openings, so that each of the second openings and each of the third openings together form a stepped groove structure.
